(19) United States
(12) Patent Application Publication
(10) Pub. No.: US 2007/0046314 A1
(43) Pub. Date: Mar. 1, 2007

(54) Process for testing IC wafer

(75) Inventors: Shin-Hua Chao, Tzuoying Chiu (TW); Yao-Hsin Feng, Hualian City (TW)

Correspondence Address: TROXELL LAW OFFICE PLLC, SUITE 1404, 5205 LEESBURG PIKE, FALLS CHURCH, VA, 22041, US

(73) Assignee: Advanced Semiconductor Engineering, Inc.

(21) Appl. No.: 11/589,735

(22) Filed: Oct. 31, 2006

Related U.S. Application Data
(63) Continuation-in-part of application No. 10/895,061, filed on Jul. 21, 2004, now abandoned.

(51) Int. Cl. G01R 31/26

(52) U.S. Cl. 324/765

(57) ABSTRACT

A process for testing IC wafer is disclosed. Prior to electrically testing chips on a wafer, the wafer is pre-cut to form a plurality of grooves aligned with the scribe lines on the active surface of the wafer. A step of singulating the wafer is performed to form a plurality of individual chips after completing electrical or reliability test of the chips. Due to the pre-cutting step the chips are still integrated on the wafer for accurately probing and testing. And the testing step can obtain the influence of defects between the test terminals and a UBM layer on the function of the chips.

### FIELD OF THE INVENTION

The present invention relates to a process for testing an IC wafer, particularly to a process combining IC wafer testing and dicing.

### BACKGROUND OF THE INVENTION

Finishing integrated circuits fabrication on a wafer, the wafer has to go through CP (chip probing) then go through dicing process to form a plurality of individual chips. A conventional wafer testing process is disclosed in R.O.C. Patent No. 445500. The conventional CP step is used to test bare chips of a wafer having bad contact points or not. But there might have side chipping during dicing the wafer. The side chipping might affect the electrical function of the good chips (Known Good Die, KGD). So after the chips are singulated, an electrical test in chip-level or package-level is needed to confirm the side chipping does not affect the electrical function of a KGD.

Conventionally CP can be merged into wafer-level assembling process. Firstly a wafer is attached to a UV tape. The wafer has been gone through assembly processes, then the wafer is diced to form a plurality of individual chips (or wafer-level chip scale packages) on the UV tape. The chips on the UV tape are tested via a probe card to check the original function and also to check if side chipping affects the electrical function of the chips or not. However, it is difficult to control the positions of the chips because that the CTE of the UV tape carrying the chips cannot match the CTE of the probe card, moreover, the dicing processes will enhance the shifting of the chip positions on the UV tape. Since the pitch of the chips on the UV tape after dicing cannot be well-controlled, therefore, the positions of the test terminals (such as bonding pads or bumps) of the chips corresponding to the UV tape are not controllable. The probe card just can test one chip at a time as single site testing. Such dicing step and testing step are neither lowering the cost nor increasing efficiency to get KGD or good packages.

### SUMMARY

The main object of the present invention is to provide a process for testing an IC wafer. A testing step is performed between a pre-cutting step and a wafer singulation step. A plurality of chips are not separated during the testing step but a plurality of grooves had formed on the wafer. So the chips not only can be tested via a probe card by multiple-site testing but also the effect of defects between the test terminals and a UBM layer has been included in the testing step.

The second object of the present invention is to provide a process for testing an IC wafer. By means of a pre-cutting step a plurality of grooves are formed on an active surface of a wafer to electrically insulate a plurality of interconnecting traces between the chips but the chips are still integrated on the wafer. So the chips can be tested in the grooved wafer with low cost and high efficiency prior to singulating the wafer.

According to the present invention, a process for testing an IC wafer includes processing steps such as follows. A wafer is provided which has an active surface and a back surface. The wafer includes a plurality of chips, a plurality of test terminals, a plurality of scribe lines between the chips and a plurality of interconnecting traces on the active surface for electrically connecting the chips. The interconnecting traces run across the scribe lines. Then, the wafer is pre-cut to form a plurality of grooves on the active surface corresponding to the scribe lines. The grooves are formed to electrically insulate the interconnecting traces, but the chips are still integrated on the wafer. After pre-cutting the wafer, the chips on the grooved wafer are tested. Then, the grooved wafer is singulated to form a plurality of individual chips.

### DESCRIPTION OF THE DRAWINGS

FIG. 1 is a flow chart of a process for testing an IC wafer in accordance with the embodiment of the present invention.

FIG. 2 is a top view of a wafer under test in accordance with the embodiment of the present invention.

FIG. 3 is a partial top view of the wafer in accordance with the embodiment of the present invention.

FIG. 4A is a cross-sectional view of the wafer in accordance with the embodiment of the present invention.

FIG. 4B is a cross-sectional view of the wafer during a pre-cutting step in accordance with the embodiment of the present invention.

FIG. 4C is a cross-sectional view of the wafer during a testing step in accordance with the embodiment of the present invention.

FIG. 4D is a cross-sectional view of the wafer during a singulating step in accordance with the embodiment of the present invention.

FIG. 5 is a cross-sectional view of detailed structure of the wafer in accordance with the embodiment of the present invention.

### DETAILED DESCRIPTION OF THE PRESENT INVENTION

Referring to the drawings attached, the present invention will be described by means of an embodiment below.

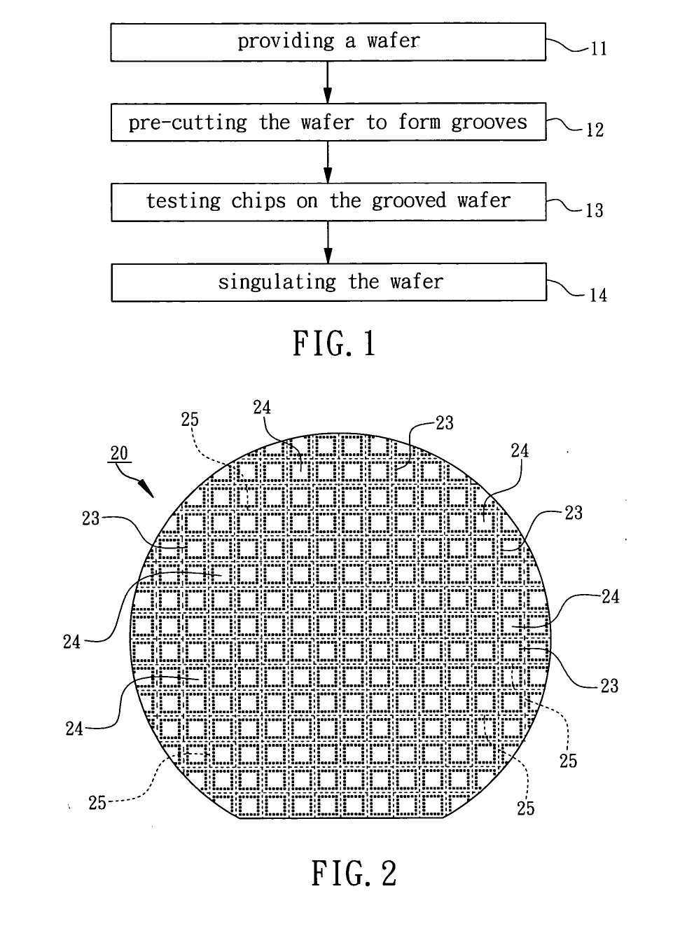

According to the present invention, a flow chart of a process for testing IC wafer is as shown in FIG. 1A, which mainly comprises: a step 11 of “providing a wafer”, a step 12 of “pre-cutting the wafer to form grooves”, a step 13 of “testing chips on the grooved wafer” and a step 14 of “singulating the wafer”.

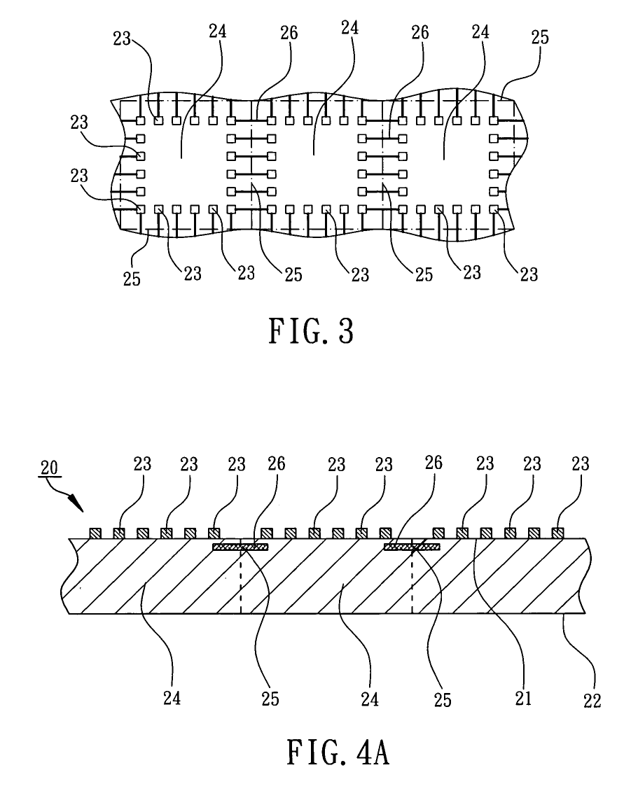

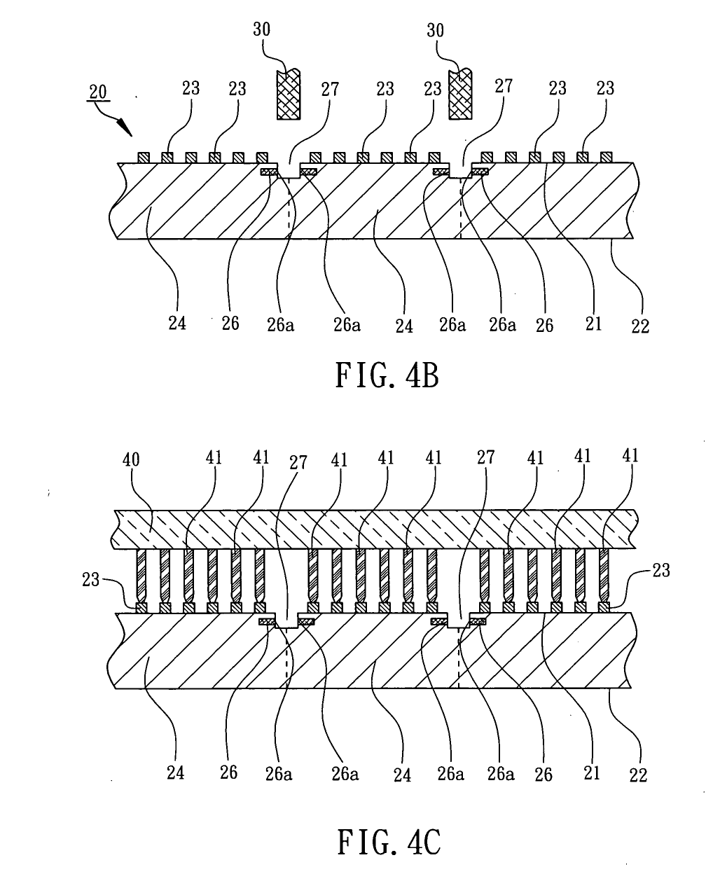

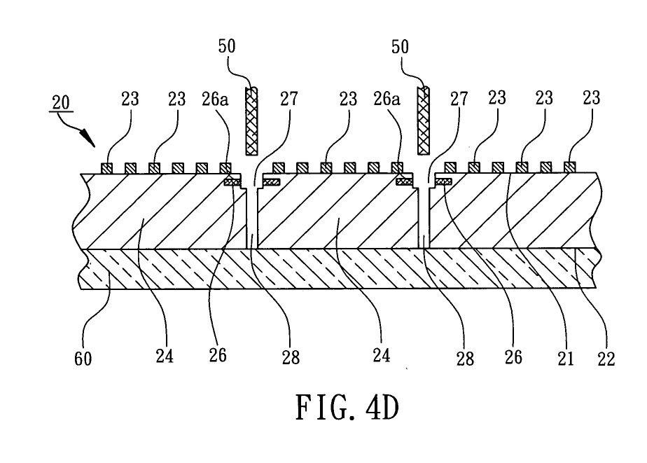

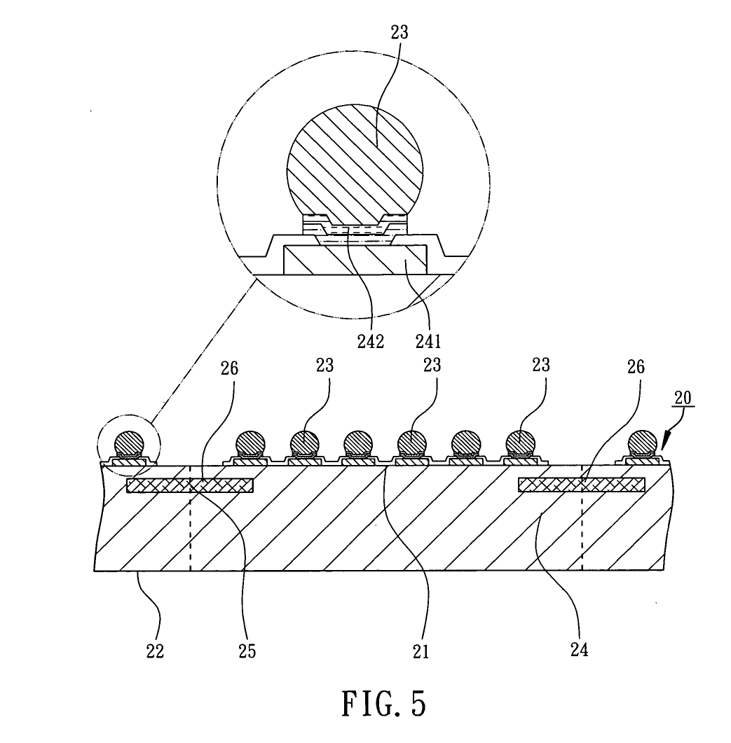

With reference to FIGS. 2, 3, 4A and 5, firstly in the step 11, a wafer 20 is provided. As shown in FIGS. 2, 4A and 5, the wafer 20 has an active surface 21 and a back surface 22, and the wafer 20 includes a plurality of chips 24 having a plurality of bonding pads 241 formed on the active surface 21, an UBM (Under Bump Metallurgy) layer 242 formed on the bonding pads 241 and a plurality of test terminals 23. The test terminals 23, such as bumps or solder balls, are formed on the UBM layer 242, in this embodiment, the test terminals 23 are bumps. Integrated circuits in each chip 24 are connected to the corresponding test terminals 23. Moreover, as shown in FIGS. 3 and 4, the wafer 20 includes a plurality of scribe lines 25 between the chips 24 and a plurality of interconnecting traces 26 connecting the chips 24. The interconnecting traces 26 are formed on the active surface 21 of the wafer 20 and run across the scribe lines 25 for electrically connecting adjacent chips 24. Normally the interconnecting traces 26 are used for burn-in test or other electrical transmitting function, but not necessary. Besides, the wafer 20 may be a kind of a wafer-level packaged wafer including solder balls (bumps), encapsulation layer or redistribution layer. And the chip 24 may be a wafer-level packaged chip before dicing so as to avoid the side chipping being formed after dicing the chips 24.

Thereafter referring to FIG. 4B, the pre-cutting step 12 is performed. As shown in FIG. 4B, a plurality of grooves 27 are formed on the active surface 21 of the wafer 20 by a sawing tool 30 or a laser-emitting equipment. The grooves 27 are aligned with the scribe lines 25 without separating the chips 24 so as to form an grooved wafer 20. Preferably, the width of the grooves 27 is about 25 um, larger than the width of the scribe lines 25. The depth of grooves 27 is less than two-thirds of a thickness of the wafer 20. In this embodiment, the scribe lines 25 are cut out from the grooves 27 until the interconnecting traces 26 between the chips 24 are electrically insulated from each other after the pre-cutting step 12. The interconnecting traces 26 have cut ends 26a exposed out of the grooves 27 to simulate the singulated conditions of the individual chips 24.

Next, the testing step 13 is performed. Referring to FIG. 4C, the grooved wafer 20 with the grooves 27 is tested by a probe card 40. The probe card 40 has a plurality of probe tips 41 for contacting the test terminals 23 of a plurality of chips 24 in array. Then the chips 24 in the grooved wafer 20 can be electrically tested by a multiple-site testing. The chips 24 are still integrated on the grooved wafer 20 in the step 12 and 13, so the pitch of the test terminals 23 will not change. The probe tips 41 of the probe card 40 can accurately contact the test terminals 23 to test the chips 24 by a multiple-site testing. In the testing step 13, the grooves 27 on the grooved wafer 20 can simulate singulated conditions of the individual chips 24 so as to determine the effect of defects between the test terminals 23 and the UBM layer 242 on the function of the chips 24 and enhance the testing reliability. Preferably, a reliability test, such as pressure cooker test or temperature cycle test, is performed after the pre-cutting step 12. Since the interconnecting traces 26 are electrically insulated by the grooves 27 and have exposed cut ends 26a, the chips 24 in the grooved wafer 20 in the testing step 13 and reliability test can be similar to real situation of the individual chips 24 after the singulating step 14.

Next, the singulating step 14 is performed. Referring to FIG. 4D, the grooved wafer 20 is attached to a UV tape 60 during the singulating step 14. The grooved wafer 20 is diced along the grooves 27 to separate the chips 24 (or called wafer-level chip scale packages) by a narrower sawing tool 50. The chips 24 are singulated and fixed on the UV tape 60. A chip pitch 28 is formed between the neighbor chips 24 by the narrower sawing tool 50. The chip pitch 28 is smaller than the grooves 27 formed in the pre-cutting step 12. The narrower sawing tool 50 cuts the grooved wafer 20 along the grooves 27, so there is less side chipping problem on the grooved wafer 20.

The above description of embodiments of this invention is intended to be illustrated but not limited. Other embodiments of this invention will be obvious to those skilled in the art in view of the above disclosure.

What is claimed is:

1. A process for testing a wafer comprising:
providing a wafer-level packaged wafer having an active surface and a back surface, the wafer-level packaged wafer including a plurality of wafer-level packaged chips and a plurality of scribe lines between the wafer-level packaged chips, wherein the wafer-level packaged chips having a plurality of bonding pads formed on the active surface, an UBM (Under Bump Metallurgy) layer formed on the bonding pads and a plurality of bumps formed on the UBM layer, and the wafer-level packaged wafer further including a plurality of interconnecting traces running across the scribe lines for electrically connecting the wafer-level packaged chips;
pre-cutting the wafer-level packaged wafer to form a grooved wafer with a plurality of grooves aligned with the scribe lines such that the interconnecting traces are broken and have a plurality of cut ends exposed out of the grooves after the pre-cutting step;
after pre-cutting, testing the wafer-level packaged chips on the grooved wafer via the bumps; and
after testing, singulating the grooved wafer to form a plurality of individual wafer-level packaged chips.

2. The process in accordance with claim 1, wherein the depth of the grooves is less than two-thirds of a thickness of the grooved wafer.

3. The process in accordance with claim 1, further comprising a reliability testing step after the pre-cutting step.

4. The process in accordance with claim 6, wherein the reliability test is a pressure cooker test.

5. The process in accordance with claim 1, wherein the bumps are contacted by a probe card during the testing step.

6. The process in accordance with claim 1, wherein the grooved wafer is attached to a tape during the singulating step.

7. The process in accordance with claim 1, wherein the wafer-level packaged chips are tested by a multiple-site testing.
